(19) United States
(12) Patent Application Publication
(10) Pub. No.: US 2023/0056554 A1
(43) Pub. Date: Feb. 23, 2023

(54) SEMICONDUCTOR CHIP CONTAINER AND FIXTURE

(71) Applicant: CHANGXIN MEMORY TECHNOLOGIES, INC., Hefei City, Anhui (CN)

(72) Inventor: Jiabao CHEN, Hefei City, Anhui (CN)

(21) Appl. No.: 17/440,874

(22) PCT Filed: Jun. 22, 2021
(86) PCT No.: PCT/CN2021/101625

§ 371 Date: Sep. 20, 2021

(30) Foreign Application Priority Data
Sep. 15, 2020 (CN) 202010970146.4

(51) Int. Cl. H01L 21/67; H01L 21/673

(52) U.S. Cl. CPC H01L 21/67271; H01L 21/67109; H01L 21/67356; H01L 21/67379; H01L 21/67386; H01L 21/67393

(57) ABSTRACT

The present disclosure relates to the technical field of semiconductors, and proposes a semiconductor chip container and a fixture. The container is placed in a containing device with a chemical reagent, and the container includes a main body and partition plates, where the main body has an accommodating space; the partition plates are arranged in the accommodating space and divide the accommodating space into a plurality of independent accommodating chambers; the plurality of accommodating chambers are respectively used for placing a plurality of independent semiconductor chips; the main body is provided with first through holes; the first through holes are used for allowing the chemical reagent to enter the accommodating space; the main body and the partition plates are used for preventing the semiconductor chip from being separated from the corresponding accommodating chamber under the action of the chemical reagent.

### CROSS REFERENCE TO RELATED APPLICATIONS

The present disclosure claims the priority to Chinese Patent Application 202010970146.4, titled “SEMICONDUCTOR CHIP CONTAINER AND FIXTURE”, filed on Sep. 15, 2020, which is incorporated herein by reference in its entirety.

### TECHNICAL FIELD

The present disclosure relates to the technical field of semiconductors, in particular to a semiconductor chip container and a fixture.

### BACKGROUND

In the failure analysis of a semiconductor chip, a plurality of stacked dies need to be properly separated for subsequent electrical and physical analysis.

In the related art, a grinding method is often used to separate the plurality of dies in sequence, which has low efficiency. A method of heating the chip with fuming nitric acid can rapidly separate the dies. However, the chip is directly placed in a containing device in the prior art. After a long time of heating, the nitric acid will be boiled, which will cause the chip to hit the containing device, thereby causing the dies to break. In addition, when dies of a plurality of chips are simultaneously separated, the dies will be disordered.

### SUMMARY

A first aspect of the present disclosure provides a semiconductor chip container. The semiconductor chip container is placed in a containing device with a chemical reagent, and the container includes:
a main body, where the main body has an accommodating space; and
partition plates, arranged in the accommodating space and dividing the accommodating space into a plurality of independent accommodating chambers, where the plurality of accommodating chambers are respectively used for placing a plurality of independent semiconductor chips;
wherein, the main body is provided with first through holes; the first through holes are used for allowing the chemical reagent to enter the accommodating space; the main body and the partition plates are used for preventing the semiconductor chip from being separated from the corresponding accommodating chamber under the action of the chemical reagent.

A second aspect of the present disclosure provides a fixture. The fixture includes the above semiconductor chip container, a containing device and a heater, where the semiconductor chip container is arranged in the containing device with a chemical reagent; the containing device is arranged on the heater.

### BRIEF DESCRIPTION OF THE DRAWINGS

The preferred implementations of the present disclosure are described in detail below with reference to the accompanying drawings to make the objectives, features and advantages of the present disclosure more obvious. The accompanying drawings are merely exemplary illustrations of the present disclosure, and are not necessarily drawn to scale. The same reference numerals in the accompanying drawings always represent the same or similar parts. Wherein:

FIG. 1 is a schematic diagram of an application structure of a fixture according to an exemplary implementation.

FIG. 2 is a schematic structural diagram of a containing device and a heater of a fixture according to an exemplary implementation.

FIG. 3 is a schematic diagram of an application structure of a container according to an exemplary implementation.

FIG. 4 is a schematic structural diagram of a container according to a first exemplary implementation.

FIG. 5 is a schematic structural diagram of a container according to a second exemplary implementation.

FIG. 6 is a schematic structural diagram of a container according to a third exemplary implementation.

FIG. 7 is a schematic diagram of an application structure of a container according to another exemplary implementation.

FIG. 8 is a schematic structural diagram of an accommodating chamber of a container according to an exemplary implementation.

FIG. 9 is a schematic structural diagram of a connecting part of the container according to an exemplary implementation.

FIG. 10 is a flowchart of a method for separating dies of a semiconductor chip according to an exemplary implementation.

### DETAILED DESCRIPTION

The typical embodiments embodying the features and advantages of the present disclosure are described in detail below. It should be understood that the present disclosure may have various changes in different embodiments without departing from the scope of the present disclosure. The description and accompanying drawings herein are essentially used for the purpose of explanation, rather than limiting the present disclosure.

Different exemplary implementations of the present disclosure are described below with reference to the accompanying drawings. The accompanying drawings form part of the present disclosure, which show by way of example different exemplary structures, systems and steps to implement various aspects of the present disclosure. It should be understood that other specific solutions of components, structures, exemplary devices, systems and steps may be used, and structural and functional modifications may be made without departing from the scope of the present disclosure. Moreover, although the terms such as “above”, “between” and “within” may be used in this specification to describe different exemplary features and elements of the present disclosure, these terms are used herein only for convenience of description, for example, according to the directions of the examples in the accompanying drawings. Nothing in this specification should be understood as requiring a specific three-dimensional direction of the structure to fall within the scope of the present disclosure.

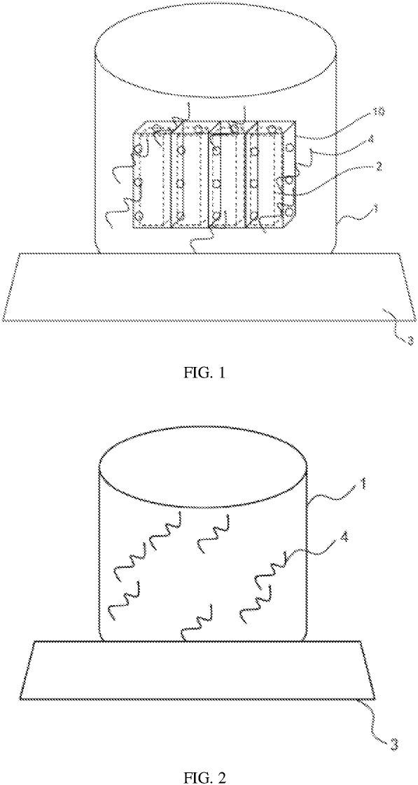

An embodiment of the present disclosure provides a semiconductor chip container. Referring to FIGS. 1 to 8, the container is placed in a containing device 1 with a chemical reagent 4. The container includes a main body 10 and partition plates 20. The main body 10 has an accommodating space. The partition plates 20 are arranged in the accommodating space and divide the accommodating space into a plurality of independent accommodating chambers 21. The plurality of accommodating chambers 21 are respectively used for placing a plurality of independent semiconductor chips 2. The main body 10 is provided with first through holes 11, and the first through holes 11 are used for allowing the chemical reagent 4 to enter the accommodating space. The main body 10 and the partition plates 20 are used to prevent the semiconductor chip 2 from being separated from the corresponding accommodating chamber 21 under the action of the chemical reagent 4.

In the container according to an embodiment of the present disclosure, the main body 10 and the partition plates 20 form a plurality of independent accommodating chambers 21. During use, each semiconductor chip 2 is placed in the corresponding accommodating chamber 21, and the container is placed in the containing device 1 with the chemical reagent 4, such that dies are separated by the chemical reagent 4. Since each semiconductor chip 2 is placed in the corresponding accommodating chamber 21, dies of the semiconductor chip 2 are located in the corresponding accommodating chamber 21 after separation, thereby avoiding the disordering of the dies of different semiconductor chips 2.

It should be noted that the size of the accommodating chamber 21 is adapted to the semiconductor chip 2, that is, the size of the accommodating chamber 21 is basically adapted to the volume of the semiconductor chip 2. Therefore, even if the semiconductor chip 2 is decapped under the action of the chemical reagent 4, the size of the accommodating chamber 21 will not be much larger than the volume of the separated dies. Even if the dies are displaced under the action of the chemical reagent 4, they will not produce a large impact force between the main body 10 and the partition plate 20, thereby preventing the dies from being broken.

In an embodiment, the main body 10 and the partition plate 20 are made of an acid and high-temperature resistant material. In this embodiment, the main body 10 and the partition plate 20 may be made of Teflon. Teflon is tough, smooth and acid-proof, which can protect the dies from collision, scratching and breaking, so as to ensure the integrity of the dies.

It should be noted that the chemical reagent 4 may be sulfuric acid or nitric acid. In this embodiment, the chemical reagent 4 is concentrated fuming nitric acid.

In an embodiment, the main body 10 is a closed structure when in use, that is, after the main body 10 is put into the chemical reagent 4, the main body 10 and the partition plate 20 can prevent each semiconductor chip 2 from being separated from the accommodating chamber 21. It should be noted that the closed structure does not mean that the main body 10 is a sealed structure. On the contrary, the main body 10 is a non-sealed structure, such that the chemical reagent 4 can enter the main body 10 through the first through hole 11 on the main body 10. Alternatively, the joints between the individual plates defining the main body 10 are not sealed, such that the chemical reagent 4 can enter to immerse the semiconductor chip 2 in the accommodating chamber 21. The closed structure means that the semiconductor chip 2 will not be separated from the accommodating chamber 21.

It should be noted that the main body 10 can be completely immersed in the chemical reagent 4 during use.

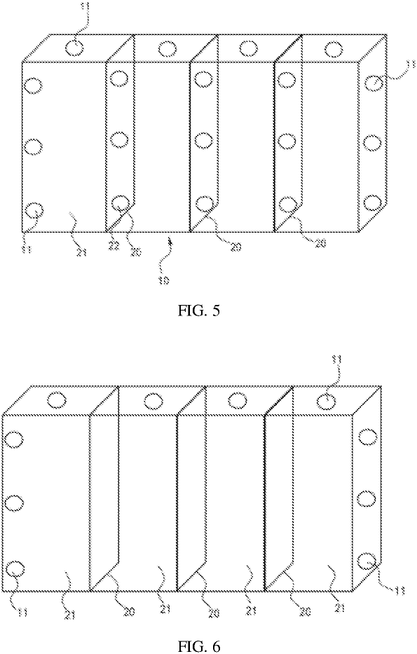

In an embodiment, as shown in FIGS. 4 and 5, each partition plate 20 is provided with second through holes 22, such that two adjacent accommodating chambers 21 communicate through the second through holes 22. In this way, the chemical reagent 4 can enter each accommodating chamber 21, that is, the chemical reagent 4 can efficiently enter the accommodating chamber 21.

It should be noted that the chemical reagent 4 enters the main body 10 through the first through hole 11 of the main body 10, but if the chemical reagent 4 cannot be directly introduced through the first through hole 11 to enter a certain accommodating chamber 21 formed by the partition plate 20, the chemical reagent 4 needs to be introduced through the second through holes 22 on the partition plate 20.

In one embodiment, as shown in FIG. 8, each accommodating chamber 21 includes sidewalls 211, a top wall 212 and a bottom wall 213. At least part of the sidewalls 211 is formed by the partition plates 20. The top wall 212 and the bottom wall 213 are formed by the main body 10. The second through holes 22 are arranged on the sidewall 211. The first through holes 11 are arranged on both of the top wall 212 and the bottom wall 213.

Specifically, the partition plate 20 isolates a plurality of independent accommodating chambers 21 in the main body 10, that is, each accommodating chamber 21 is located inside the main body 10. Therefore, the top wall 212 and the bottom wall 213 of the accommodating chamber 21 are formed by the main body 10. The sidewall 211 of the accommodating chamber 21 may be formed by the main body 10 and the partition plate 20 together. Alternatively, the sidewall 211 of the accommodating chamber 21 may be separately formed by the partition plate 20. Therefore, in order to enable the chemical reagent 4 to quickly enter into each accommodating chamber 21, a through hole (that is, the first through hole 11 and/or the second through hole 22) may be provided on the sidewall 211 of each accommodating chamber 21. The first through holes 11 are arranged on both of the top wall 212 and the bottom wall 213.

In an embodiment, the top wall 212 and the bottom wall 213 of each accommodating chamber 21 are respectively provided with at least one first through hole 11. The sidewall 211 of each accommodating chamber 21 may be provided with a plurality of through holes in columns. In this embodiment, the accommodating chamber 21 is a rectangular chamber. The rectangular chamber has four intersecting sidewalls 211, and each sidewall 211 is provided with a plurality of through holes. For example, each sidewall 211 may be provided with three through holes.

In an embodiment, the first through hole 11 and the second through hole 22 may be round holes, polygonal holes or special-shaped holes, which are not limited herein, as long as the chemical reagent 4 can quickly pass through the through holes.

It should be noted that the sizes of the first through hole 11 and the second through hole 22 need to be smaller than that of the semiconductor chip 2 to prevent the semiconductor chip 2 from being separated from the accommodating chamber 21. Further, the sizes of the first through hole 11 and the second through hole 22 need to be smaller than the minimum size of the die.

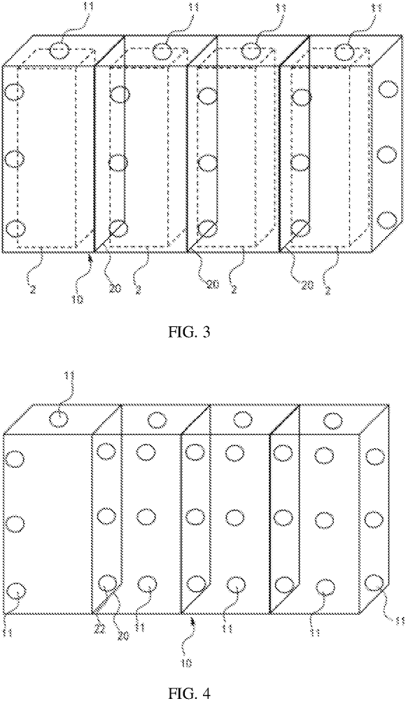

In an embodiment, as shown in FIGS. 3 to 7, there is at least one partition plate 20. The at least one partition plate 20 is arranged in the accommodating space to divide the accommodating space into at least two accommodating chambers 21. That is, at least two semiconductor chips 2 may be placed in each container at the same time.

In an embodiment, the accommodating chambers 21 are in a row, that is, as shown in FIGS. 3 to 6, a plurality of independent accommodating chambers 21 are arranged in sequence to form a row. Specifically, a plurality of partition plates 20 are arranged in the main body 10 at intervals along a certain direction, thereby dividing the accommodating space of the main body 10 into a plurality of accommodating chambers 21.

In this embodiment, the sidewall 211 of the accommodating chamber 21 is formed by the main body 10 and the partition plate 20 together. A plurality of first through holes 11 are arranged on the main body 10 surrounding the accommodating chamber 21. Each partition plate 20 is provided with the second through hole 22, as shown in FIGS. 4 and 5. Alternatively, the partition plate 20 may not be provided with the second through hole 22, as shown in FIG. 6.

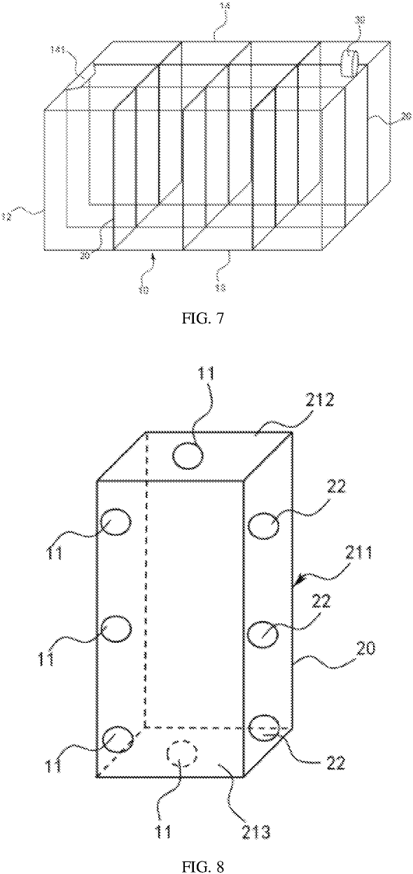

In an embodiment, the accommodating chambers 21 are in a plurality of rows, that is, as shown in FIG. 7, a plurality of independent accommodating chambers 21 are sequentially arranged in two directions and in a plurality of rows. Specifically, a plurality of partition plates 20 intersect to divide the accommodating space in the main body 10 in a crossed pattern. For example, when there are four accommodating chambers 21, there may be two partition plates 20. The two partition plates 20 are arranged crosswise, so as to divide four accommodating chambers 21 in the main body 10. In this case, one partition plate 20 needs to be inserted to the other partition plate 20. Alternatively, there may be three partition plates 20, and two small partition plates 20 are connected with two sides of a large partition plate 20, respectively. Alternatively, there may be four partition plates 20, and the four partition plates 20 may be respectively connected at the periphery of the main body 10. Alternatively, four accommodating chambers 21 may be formed by two L-shaped partition plates 20.

In this embodiment, there are 12 accommodating chambers 21. The accommodating chambers 21 are arranged in 3 rows and 4 columns. The sidewalls 211 of the two accommodating chambers 21 in the center are formed by partition plates 20, and the sidewalls 211 of the other accommodating chambers 21 are formed by the main body 10 and partition plates 20 together. The structure and arrangement of the partition plates 20 are not limited herein, and the specific structure of the partition plates 20 when there are four accommodating chambers 21 may be referred to. It should be noted that the first through hole 11 and the second through hole 22 are not shown in FIG. 7.

In an embodiment, there are a plurality of accommodating chambers 21. The plurality of accommodating chambers 21 may be arranged in a ring shape. For example, when the main body 10 has a rectangular structure or a cylindrical structure, the accommodating space of the main body 10 may be divided in a star pattern. Alternatively, when the partition plate 20 is an arc-shaped plate, a plurality of accommodating chambers 21 with an irregular shape may be divided inside the main body 10. The specific form and distribution of the partition plate 20 are not limited herein, as long as the accommodating chambers 21 can be divided for storing the semiconductor chips 2.

In an embodiment, as shown in FIG. 7, the main body 10 includes side plates 12, a bottom plate 13 and a top plate 14. The bottom plate 13 is connected with a lower end of the side plates 12. The top plate 14 is connected with an upper end of the side plate 12. The side plates 12, the bottom plate 13 and the top plate 14 form an accommodating space, and at least one of the side plates 12, the bottom plate 13 and the top plate 14 is provided with the first through holes 11. At least one of the side plates 12 and the bottom plate 13 is connected with the partition plates 20. The top plate 14 is movably arranged relative to the side plates 12 so as to open or close the accommodating chamber 21.

Specifically, the side plates 12, the bottom plate 13 and the top plate 14 of the main body 10 form a closed structure, and the partition plate 20 is located in the closed structure to separate a plurality of accommodating chambers 21 in the closed structure. In order to hold the semiconductor chip 2 in the accommodating chamber 21 without being separated from the accommodating chamber 21 during the separation process of the dies of the semiconductor chip, the top plate 14 is movably provided relative to the side plates 12 so as to open or close the accommodating chamber 21.

In an embodiment, as shown in FIG. 7, an operating handle 141 is arranged on the top plate 14. The operating handle 141 is used for an operator to pull the top plate 14 such that the top plate 14 moves relative to the side plate 12. The operating handle 141 may be a protruding structure or a recessed structure to facilitate the operator’s hand grasping. The top plate 14 and the side plate 12 may be in a pull-out connection, similar to a common pull-out drawer. A slide rail may be arranged on the side plate 12, and the top plate 14 may be inserted into the slide rail. Thus, when the top plate 14 moves relative to the side plate 12, the top plate 14 is limited so as to prevent the top plate 14 from being separated from the side plate 12.

It should be noted that the top plate 14 may be completely pulled out from the side plate 12, or when the top plate 14 is pulled to a certain position, it will be limited with the side plate 12 by a limiting structure, so as to control the moving range of the top plate 14 and prevent the top plate 14 from being separated.

In an embodiment, the operating handle 141 may be made of the same material as the main body 10, that is, an acid and high-temperature resistant material. In this embodiment, the material of the operating handle 141 may be Teflon.

In an embodiment, the partition plates 20 is fixedly connected with the main body 10. The size of the accommodating chamber 21 is determined according to that of the semiconductor chip 2, and an appropriate mounting position is selected to fix the partition plate 20 such that the accommodating chamber 21 is fixed in size. This structure may be used for a separation occasion where the size range of the semiconductor chip 2 is relatively determined.

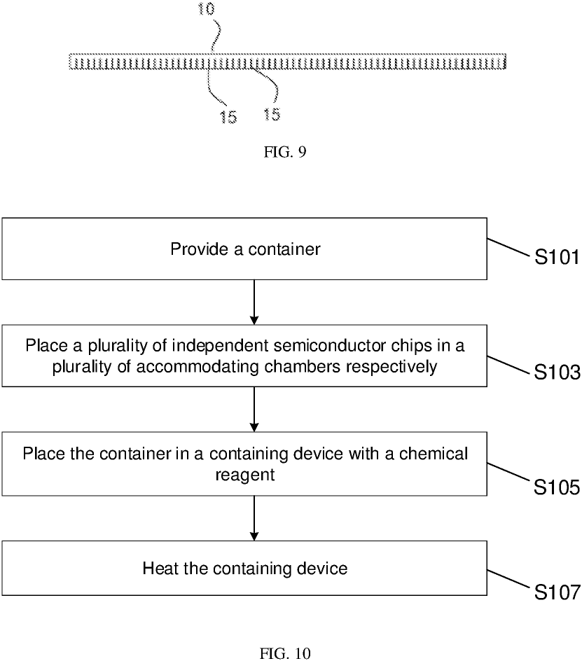

In an embodiment, as shown in FIG. 9, a plurality of connecting parts 15 are arranged on the main body 10. Each partition plate 20 is selectively connected with one of the plurality of connecting parts 15 to adjust the size of the accommodating chamber 21. That is, the partition plates 20 may be selectively connected with different connecting parts 15 according to the size of the semiconductor chip 2 to make the accommodating chamber 21 adapted to the size of the semiconductor chip 2. Thus, the accommodating chamber is made versatile for different models of semiconductor chips 2. It should be noted that FIG. 9 is only used to illustrate the arrangement of the connecting parts 15 and does not specifically specify the relevant structure of the main body 10.

Specifically, a plurality of connecting parts 15 are arranged on the main body 10. The side plate 12 of the main body 10 may be provided with a plurality of connecting parts 15. Alternatively, the bottom plate 13 may be provided with a plurality of connecting parts 15, or the side plate 12 and the bottom plate 13 may be respectively provided with a plurality of connecting parts 15. In this case, the connecting parts 15 on the bottom plate 13 and the side plate 12 may be in the same plane, or they may be arranged in a staggered manner. In specific use, the actually used connecting parts 15 are determined according to the size of the semiconductor chip 2, so as to form a plurality of accommodating chambers 21 at corresponding positions of the main body 10 to contain the plurality of semiconductor chips 2. The semiconductor chips 2 may be of the same model or different models. That is, the sizes of the plurality of accommodating chambers 21 may be all equal, or all may be unequal, or partly equal, partly unequal.

In an embodiment, the connecting parts 15 may be arranged in pairs. For example, the two sides of the bottom plate 13 are respectively provided with connecting parts 15, and the partition plate 20 is connected with the pair of connecting parts 15.

In an embodiment, the partition plates 20 are detachably connected with the connecting parts 15. The partition plate 20 is connected with different connecting parts 15 according to different models of semiconductor chips 2 so as to improve the versatility of the container.

In an embodiment, the partition plates 20 are clamped to the connecting parts 15, so as to facilitate the assembly and disassembly of the partition plate 20, thereby improving the use efficiency.

In an embodiment, the connecting parts 15 each is a groove, and the partition plate 20 is inserted into the groove. Alternatively, the connecting parts 15 each is a protrusion, a groove adapted to the protrusion are arranged on the partition plate 20, and the protrusion is inserted into the groove. The protrusion and groove structure can ensure the effective connection between the partition plate 20 and the connecting part 15, and facilitate the assembly and disassembly of the partition plate 20. The groove actually prevents the partition plate 20 from falling over.

In an embodiment, as shown in FIG. 7, the semiconductor chip container further includes a suspending part 30. Two ends of the suspending part 30 are respectively connected with the main body 10 and the containing device 1 to suspend the main body 10 in the containing device 1, so as to facilitate the chemical reagent 4 to completely immerse the main body 10.

It should be noted that, in an embodiment, the main body 10 may be suspended in the center of the containing device 1 by the suspending part 30 such that there is a certain gap between the main body 10 and an inner wall of the containing device 1. In this way, the first through hole 11 arranged on the main body 10 will not be blocked by the containing device 1 and the chemical reagent can flow normally through the first through hole 11.

It should be noted that the suspending part 30 may be a hook. One end of the suspending part 30 is connected with the main body 10, and the other end thereof is directly suspended to the containing device 1. The hook may be directly suspended into the first through hole 11 of the main body 10 to realize the connection between the suspending part 30 and the main body 10. Alternatively, the suspending part 30 may be a handle-like structure, which may be directly suspended to the containing device 1 or held by the operator. The specific structure of the suspending part 30 is not limited, as long as the connection can be achieved.

In an embodiment, the suspending part 30 includes a first suspending component and a second suspending component. The first suspending component and the second suspending component are connected, and the first suspending component and the second suspending component are respectively connected with the main body 10 and the containing device 1. The first suspending component and the second suspending component may be integrally formed, and the first suspending component and the second suspending component may also be independently formed. The first suspending component and the second suspending component are used to realize a detachable connection. When the first suspending component connected with the main body 10 is directly connected with the second suspending component, the main body 10 is suspended to the containing device 1. The first suspending component and the second suspending component may be simply clamped or simply suspended. That is, two hooks are directly connected, or a hook body is connected with a hole, which is not limited herein, as long as it is easy to disassemble.

In an embodiment, the main body 10 and the first suspending component may be integrated, or may be formed separately and then fixedly connected. The containing device 1 and the second suspending component may be integrated, or may be formed separately and then fixedly connected.

In an embodiment, there may be a plurality of suspending parts 30, that is, the main body 10 may be stably suspended to the containing device 1 by the plurality of suspending parts 30.

In an embodiment, the suspending part 30 includes a section made of an acid and high-temperature resistant material. That is, a part immersed in the chemical reagent 4 may be made of Teflon, and the other part may be made of a suitable material, such as commonly used metal materials, etc. Of course, the suspending part 30 may also be made of an acid and high-temperature resistant material as a whole. In this embodiment, the suspending part 30 is made of Teflon.

An embodiment of the present disclosure further provides a fixture. Referring to FIGS. 1 and 2, the fixture includes the above semiconductor chip container, a containing device 1 and a heater 3. The semiconductor chip container is arranged in the containing device 1 with a chemical reagent 4, and the containing device 1 is arranged on the heater 3.

In the fixture according to an embodiment of the present disclosure, the dies of the semiconductor chip 2 can be quickly separated by using the container, the containing device 1, the heater 3 and the chemical reagent 4 placed in the containing device 1. Since each semiconductor chip 2 is placed in a corresponding accommodating chamber 21, the dies of the semiconductor chip 2 are located in the corresponding accommodating chamber 21 after separation, thereby avoiding the disordering of the dies of different semiconductor chips 2.

In an embodiment, the containing device 1 may be a beaker, and the beaker is placed on the heater 3 for heating. The beaker is filled with concentrated sulfuric acid or concentrated nitric acid for a chemical decapping operation of the semiconductor chip 2 to be decapped. The heater 3 is used to heat the concentrated sulfuric acid or concentrated nitric acid in the beaker to reach a decapping heating condition of the semiconductor chip 2.

In an embodiment, the heater 3 may be an electric heating furnace.

An embodiment of the present disclosure further provides a method for separating a die of a semiconductor chip. Referring to FIG. 10, the method includes:

S101: Provide a container, where the container includes a main body 10 and a partition plate 20, and the partition plate 20 divides a plurality of independent accommodating chambers 21 in the main body 10.

S103: Place a plurality of independent semiconductor chips 2 in the plurality of accommodating chambers 21 respectively.

S105: Place the container in a containing device 1 with a chemical reagent 4, and make the chemical reagent 4 immerse each semiconductor chip 2, where the semiconductor chip 2 cannot be separated from the corresponding accommodating chamber 21 under the action of the chemical reagent 4.

S107: Heat the containing device 1 to separate dies of the semiconductor chip 2.

In the method for separating a die of a semiconductor chip according to an embodiment of the present disclosure, a plurality of semiconductor chips 2 are respectively placed in an independent accommodating chamber 21 inside a containing device 1 with a chemical reagent 4, and the dies of the semiconductor chip 2 are quickly separated by heating the chemical reagent 4. Since each semiconductor chip 2 is placed in a corresponding accommodating chamber 21, the dies of the semiconductor chip 2 are located in the corresponding accommodating chamber 21 after separation, thereby avoiding the disordering of the dies of different semiconductor chips 2.

It should be noted that the die separation process is actually a decapping process of the semiconductor chip 2. The chemical reagent 4 reacts with an encapsulant to realize the separation of the dies. The chemical reagent 4 may be concentrated sulfuric acid or concentrated nitric acid. In this embodiment, the chemical reagent 4 is fuming nitric acid.

In an embodiment, the method for separating a die of a semiconductor chip uses the above fixture, which is specifically as follows:

The semiconductor chip 2 is put into the main body 10, and the main body 10 is suspended in the containing device 1 by the suspending part 30.

The fuming nitric acid is added into the containing device 1 to immerse the main body 10, and the containing device 1 is placed on the heater 3. Turn on the heater 3, set the temperature as 220° C.~240° C., and take out the main body 10 after heating for 1.2 h~1.5 h.

The main body 10 is rinsed under clean water to remove the acid residue. Then the main body 10 is opened, and the dies are taken out, cleaned and gently blown dry with a nitrogen gun, and put into a sample box.

In the method for separating a die of a semiconductor chip in the present disclosure, the semiconductor chips 2 are placed in the accommodating chambers 21 in batches by the container, and it only takes 1.5 h to complete the separation of a plurality of stacked dies. This method avoids the break of the dies, and greatly saves the time for separating the dies to ensure the smooth progress of subsequent tests.

A person skilled in the art may easily think of other implementation solutions of the present disclosure after considering the specification and practicing the present disclosure disclosed herein. The present disclosure is intended to cover any variations, purposes or applicable changes of the present disclosure. Such variations, purposes or applicable changes follow the general principle of the present disclosure and include common knowledge or conventional technical means in the technical field which is not disclosed in the present disclosure. The specification and implementations are merely considered as exemplary, and the real scope and spirit of the present disclosure are directed by the appended claims.

It should be noted that, the present disclosure is not limited to the precise structures that have been described above and shown in the accompanying drawings, and can be modified and changed in many ways without departing from the scope of the present disclosure. The scope of the present disclosure is formed only by the appended claims.

1. A semiconductor chip container, wherein the semiconductor chip container is placed in a containing device with a chemical reagent, and the semiconductor chip container comprises:
a main body, wherein the main body has an accommodating space; and
partition plates, arranged in the accommodating space and dividing the accommodating space into a plurality of independent accommodating chambers, wherein the plurality of accommodating chambers are respectively used for placing a plurality of independent semiconductor chips;
wherein, the main body is provided with first through holes; the first through holes are used for allowing the chemical reagent to enter the accommodating space; the main body and the partition plates are used for preventing the semiconductor chip from being separated from the corresponding accommodating chamber under the action of the chemical reagent.

2. The semiconductor chip container according to claim 1, wherein each partition plate is provided with second through holes to communicate two adjacent accommodating chambers with each other.

3. The semiconductor chip container according to claim 2, wherein each accommodating chamber comprises sidewalls, a top wall and a bottom wall; at least part of the sidewalls is formed by the partition plates; the top wall and the bottom wall are formed by the main body.

4. The semiconductor chip container according to claim 3, wherein the second through holes are arranged on the sidewalls; the first through holes are arranged on both of the top wall and the bottom wall.

5. The semiconductor chip container according to claim 1, wherein there is at least one partition plate; the at least one partition plate is provided in the accommodating space to divide the accommodating space into at least two accommodating chambers.

6. The semiconductor chip container according to claim 1, wherein the main body comprises:
side plates;
a bottom plate, wherein the bottom plate is connected with a lower end of the side plates; and
a top plate, wherein the top plate is connected with an upper end of the side plate; the side plates, the bottom plate and the top plate form the accommodating space; at least one of the side plates, the bottom plate and the top plate is provided with the first through holes;
wherein, at least one of the side plates and the bottom plate is connected with the partition plates; the top plate is movably arranged relative to the side plates so as to open or close the accommodating chamber.

7. The semiconductor chip container according to claim 6, wherein an operating handle is arranged on the top plate.

8. The semiconductor chip container according to claim 7, wherein the operating handle is made of the same material as the main body.

9. The semiconductor chip container according to claim 1, wherein the partition plates are fixedly connected with the main body.

10. The semiconductor chip container according to claim 1, wherein the main body is provided with a plurality of connecting parts; each partition plate is selectively connected with one of the plurality of connecting parts to adjust a size of the accommodating chamber.

11. The semiconductor chip container according to claim 10, wherein the partition plates are detachably connected with the connecting parts.

12. The semiconductor chip container according to claim 11, wherein the partition plates are clamped to the connecting parts.

13. The semiconductor chip container according to claim 12, wherein the connecting parts each is a groove, and the partition plate is inserted into the groove; alternatively, the connecting parts each is a protrusion, a groove adapted to the protrusion are arranged on the partition plate, and the protrusion is inserted into the groove.

14. The semiconductor chip container according to claim 1, wherein the semiconductor chip container further comprises:
a suspending part, wherein two ends of the suspending part are respectively connected with the main body and the containing device to suspend the main body in the containing device.

15. A fixture, comprising the semiconductor chip container according to claims 1, a containing device and a heater, wherein the semiconductor chip container is arranged in the containing device with a chemical reagent; the containing device is arranged on the heater.

16. The semiconductor chip container according to claim 2, wherein the partition plates are fixedly connected with the main body.

17. The semiconductor chip container according to claim 3, wherein the partition plates are fixedly connected with the main body.

18. The semiconductor chip container according to claim 2, wherein the main body is provided with a plurality of connecting parts; each partition plate is selectively connected with one of the plurality of connecting parts to adjust a size of the accommodating chamber.

19. The semiconductor chip container according to claim 3, wherein the main body is provided with a plurality of connecting parts; each partition plate is selectively connected with one of the plurality of connecting parts to adjust a size of the accommodating chamber.
